(19) United States
(12) Patent Application Publication
(10) Pub. No.: US 2024/0170569 A1
(43) Pub. Date: May 23, 2024

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Keiji OKUMURA, Matsumoto-city (JP)

(73) Assignee: FUJI ELECTRIC CO., LTD., Kawasaki-shi (JP)

(21) Appl. No.: 18/473,431

(22) Filed: Sep. 25, 2023

(30) Foreign Application Priority Data
Nov. 22, 2022 (JP) 2022-186720

(51) Int. Cl. H01L 29/78; H01L 29/06; H01L 29/16; H01L 29/66

(52) U.S. Cl. CPC H01L 29/7813; H01L 29/0619; H01L 29/1608; H01L 29/66712

(57) ABSTRACT

A semiconductor device includes: a drift layer; a base region provided on the drift layer; a main region provided on the drift layer; a gate electrode provided on the drift layer and buried in a gate trench extending in one direction across both ends of an active part with a gate insulating film interposed; a gate runner provided on an outer circumferential side of the active part so as to be electrically connected to the gate electrode; a gate pad provided on an inner side of the gate runner; and a resistance layer provided on the drift layer and buried in a trench for resistance extending in the one direction across the both ends of the active part with an insulating film interposed so as to be electrically connected between the gate pad and the gate runner.

### CROSS-REFERENCE TO RELATED APPLICATION

This application claims benefit of priority under 35 USC 119 based on Japanese Patent Application No. 2022-186720 filed on Nov. 22, 2022, the entire contents of which are incorporated by reference herein.

### BACKGROUND OF THE INVENTION

### 1. Field of the Invention

The present invention relates to a semiconductor device and a method of manufacturing the same.

### 2. Description of the Related Art

JP 2008-294301 A discloses a semiconductor device including an IGBT element having a trench-type gate electrode and a plurality of trench-type internal gate resistors each serving as a resistance element connected in parallel, in which a length of the respective internal gate resistors is adjusted so as to change a resistance value.

JP 2019-161200 A discloses a double-trench structure including a source trench and a gate trench, the source trench having a greater depth than the gate trench.

It is hard to lead the gate resistors to be arranged inside such a conventional trench-gate semiconductor device when formed on the top surface of a substrate via an insulating film since the number of manufacturing steps inevitably increases.

### SUMMARY OF THE INVENTION

In view of the foregoing problems, the present invention provides a semiconductor device having a configuration capable of facilitating an arrangement of a gate resistor inside the semiconductor device, and also provides a method of manufacturing the same.

An aspect of the present invention inheres in a semiconductor device including: a drift layer of a first conductivity-type provided in an active part and a terminal part located along a circumference of the active part; a base region of a second conductivity-type provided on a top surface side of the drift layer in the active part; a main region of the first conductivity-type provided on the top surface side of the drift layer in the active part so as to be in contact with the base region; a gate electrode provided on the top surface side of the drift layer in the active part and buried in a gate trench extending in one direction across both ends of the active part with a gate insulating film interposed; a gate runner provided on an outer circumferential side of the active part so as to be electrically connected to the gate electrode; a gate pad provided on an inner side of the gate runner in the active part; and a resistance layer provided on the top surface side of the drift layer in the active part and buried in a trench for resistance extending in the one direction across the both ends of the active part with an insulating film interposed so as to be electrically connected between the gate pad and the gate runner.

Another aspect of the present invention inheres in a method of manufacturing a semiconductor device including: forming a drift layer of a first conductivity-type in an active part and a terminal part located along a circumference of the active part; forming a base region of a second conductivity-type on a top surface side of the drift layer in the active part; forming a main region of the first conductivity-type on the top surface side of the drift layer in the active part so as to be in contact with the base region; forming a gate trench extending in one direction across both ends of the active part on the top surface side of the drift layer in the active part; burying a gate electrode in the gate trench with a gate insulating film interposed; forming a gate runner on an outer circumferential side of the active part so as to be electrically connected to the gate electrode; forming a gate pad on an inner side of the gate runner in the active part; forming a trench for resistance extending in the one direction across the both ends of the active part on the top surface side of the drift layer in the active part; and burying a resistance layer in the trench for resistance with an insulating film interposed so as to be electrically connected between the gate pad and the gate runner.

### BRIEF DESCRIPTION OF THE DRAWINGS

FIG. 1 is a schematic plan view illustrating an example of a semiconductor device according to a first embodiment;

FIG. 2 is an enlarged schematic plan view of region A in FIG. 1;

FIG. 3 is a schematic cross-sectional view taken along line A-A′ in FIG. 2;

FIG. 4 is a schematic cross-sectional view taken along line B-B′ in FIG. 2;

FIG. 5 is a schematic cross-sectional view taken along line C-C′ in FIG. 2;

FIG. 6 is a schematic diagram illustrating an example of a semiconductor module according to the first embodiment;

FIG. 7 is a schematic plan view illustrating a semiconductor device of a comparative example;

FIG. 8 is a schematic cross-sectional view for explaining an example of a method of manufacturing the semiconductor device according to the first embodiment;

FIG. 9 is a schematic cross-sectional view continued from FIG. 8, for explaining the example of the method of manufacturing the semiconductor device according to the first embodiment;

FIG. 10 is a schematic cross-sectional view continued from FIG. 9, for explaining the example of the method of manufacturing the semiconductor device according to the first embodiment;

FIG. 11 is a schematic cross-sectional view continued from FIG. 10, for explaining the example of the method of manufacturing the semiconductor device according to the first embodiment;

FIG. 12 is a schematic cross-sectional view continued from FIG. 11, for explaining the example of the method of manufacturing the semiconductor device according to the first embodiment;

FIG. 13 is a schematic cross-sectional view continued from FIG. 12, for explaining the example of the method of manufacturing the semiconductor device according to the first embodiment;

FIG. 14 is a schematic cross-sectional view continued from FIG. 13, for explaining the example of the method of manufacturing the semiconductor device according to the first embodiment;

FIG. 15 is a schematic cross-sectional view continued from FIG. 14, for explaining the example of the method of manufacturing the semiconductor device according to the first embodiment;

FIG. 16 is a schematic cross-sectional view illustrating an example of a semiconductor device according to a second embodiment;

FIG. 17 is a schematic cross-sectional view illustrating an example of a semiconductor device according to a third embodiment;

FIG. 18 is a schematic cross-sectional view illustrating an example of a semiconductor device according to a fourth embodiment;

FIG. 19 is a schematic cross-sectional view illustrating an example of a semiconductor device according to a fifth embodiment;

FIG. 20 is a schematic cross-sectional view illustrating an example of a semiconductor device according to a sixth embodiment;

FIG. 21 is a schematic cross-sectional view illustrating an example of a semiconductor device according to a seventh embodiment;

FIG. 22 is a schematic cross-sectional view illustrating an example of a semiconductor device according to an eighth embodiment;

FIG. 23 is a schematic plan view illustrating an example of a semiconductor device according to a ninth embodiment; and

FIG. 24 is a schematic plan view illustrating an example of a semiconductor device according to a tenth embodiment.

### DETAILED DESCRIPTION

With reference to the drawings, first to tenth embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to tenth embodiments described below merely illustrate schematically devices and methods for specifying and giving shapes to the technical idea of the present invention, and the span of the technical idea is not limited to materials, shapes, structures, and relative positions of elements described herein.

As used in the present specification, a source region of a MOS transistor such as a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOS transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, an “upper surface” may be read as “front surface”, and a “lower surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

### First Embodiment

<Structure of Semiconductor Device>

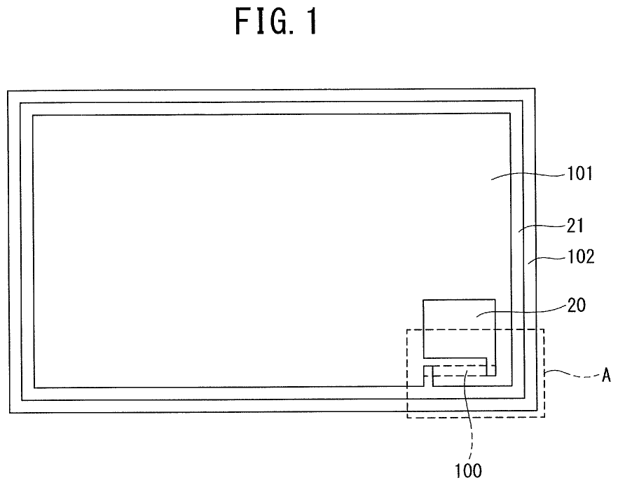

A semiconductor device (a semiconductor chip) according to a first embodiment includes an active part 101 including an active element, and a terminal part 102 having a voltage blocking structure and provided along the circumference of the active part 101, as illustrated in FIG. 1. The active part 101 has a rectangular planar pattern. A gate runner (also referred to as a “gate finger”) 21 is provided on the outer circumferential side of the active part 101. The gate runner 21 has a frame-like planar pattern. The gate runner 21 is electrically connected to a gate electrode of the active element included in the active part 101.

A gate pad 20 is provided in a part of the active part 101. The gate pad 20 can be connected with bonding wires, and a gate drive circuit is connected to the gate pad 20 via the bonding wires. An internal resistance part 100 is provided between the gate pad 20 and the gate runner 21. The gate pad 20 and the gate runner 21 are electrically connected to each other via the internal resistance part 100.

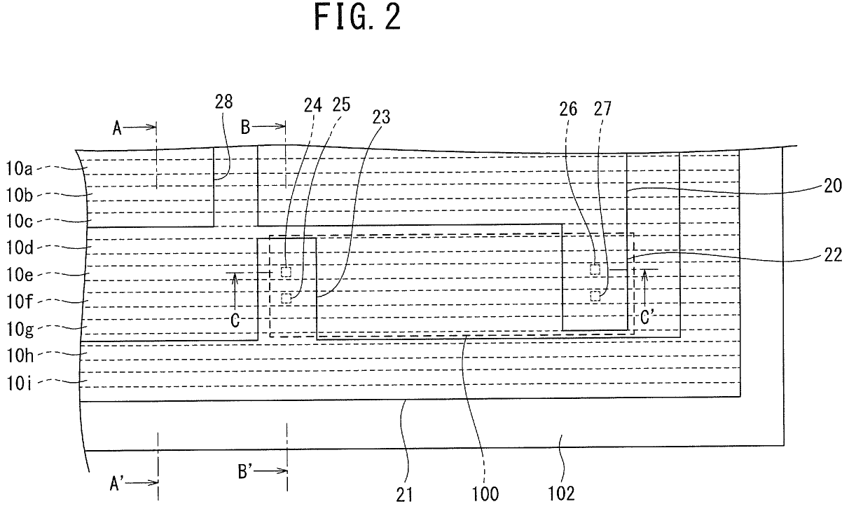

FIG. 2 is an enlarged schematic plan view of region A surrounding the circumference of the internal resistance part 100 illustrated in FIG. 1. FIG. 2 schematically indicates trenches 10a to 10i included in the semiconductor device according to the first embodiment by the broken lines. The respective trenches 10a to 10i have a stripe-shaped planar pattern extending in one direction (in the right-left direction in FIG. 2) across both ends of the active part 101. The respective trenches 10a to 10i have substantially the same width and are arranged at substantially the same intervals. The positions on both sides of the respective trenches 10a to 10i in the longitudinal direction conform to the respective end parts at the outer circumference of the active part 101. The semiconductor device according to the first embodiment includes a plurality of trenches similar to the trenches 10a to 10i in the entire region of the active part 101.

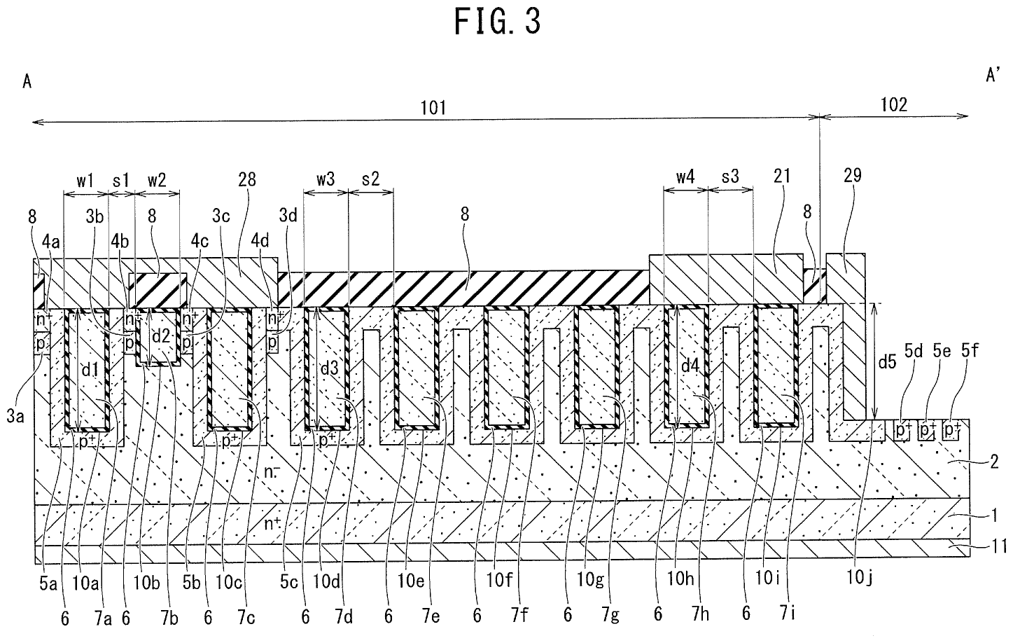

FIG. 3 is a schematic cross-sectional view taken along line A-A′ in FIG. 2. As illustrated in FIG. 3, the semiconductor device according to the first embodiment includes a drift layer 2 of a first conductivity-type (n″-type) provided across the active part 101 and the terminal part 102. The drift layer 2 is an epitaxially-grown layer including silicon carbide (SiC).

FIG. 3 illustrates a case in which the active part 101 includes a metal-oxide-semiconductor field-effect transistor (MOSFET) having a trench gate structure as the active element. The active part 101 is provided with base regions 3a to 3d of a second conductivity-type (p-type) selectively at the upper part of the drift layer 2. First main regions (source regions) 4a to 4d of n⁺-type are selectively provided on the top surface side of the base regions 3a to 3d so as to be in contact with the base regions 3a to 3d respectively.

The trenches (source trenches) 10a and 10c and the trench (gate trench) 10b interposed between the source trenches 10a and 10c are each dug from the top surface of the drift layer 2 in the depth direction that is the normal direction with respect to the top surface of the drift layer 2. The semiconductor device according to the first embodiment thus has a double-trench structure including the gate trench 10b and the source trenches 10a and 10c. The semiconductor device according to the first embodiment may have a trench gate structure only including the gate trench 10b without including the source trench 10a or 10c instead. While FIG. 3 illustrates a part of the active part 101, the semiconductor device has a structure in which a unit including the source trench 10a and the gate trench 10b is repeatedly arranged in the active part 101

A depth d1 of the respective source trenches 10a and 10c is greater than a depth d2 of the gate trench 10b. The depth d1 of the respective source trenches 10a and 10c may be substantially the same as the depth d2 of the gate trench 10b. A width w1 of the respective source trenches 10a and 10c is substantially the same as a width w2 of the gate trench 10b. The width w1 of the respective source trenches 10a and 10c may be different from the width w2 of the gate trench 10b. The source trenches 10a and 10 are each separated from the gate trench 10b at intervals s1.

The source region 4a and the base region 3a are provided in a mesa part on the left side of the source trench 10a. The term “mesa part” as used herein refers to a part interposed between the trenches adjacent to each other in the drift layer 2, and is defined as a part located at a higher position than the bottom surface of the respective trenches. The source region 4b and the base region 3b are provided in the mesa part interposed between the source trench 10a and the gate trench 10b. The source region 4c and the base region 3c are provided in the mesa part interposed between the gate trench 10b and the source trench 10c. The source region 4d and the base region 3d are provided in the mesa part on the right side of the source trench 10c.

The source region 4b and the base region 3b are in contact with the side surface on the left side of the gate trench 10b. The source region 4c and the base region 3c are in contact with the side surface on the right side of the gate trench 10b. An insulating film 6 as a gate insulating film is provided along the bottom surface and the side surfaces on both sides of the gate trench 10b. A gate electrode 7b is buried inside the gate trench 10b with the insulating film 6 interposed. The insulating film 6 that is the gate insulating film and the gate electrode 7b buried in the gate trench 10b implement an insulated gate electrode structure (6, 7b). The insulated gate electrode structure (6, 7b) regulates a surface potential of the base regions 3b and 3c at a part in contact with the respective side surfaces of the gate trench 10b.

The insulating film 6 as used herein can be a silicon oxide (SiO₂) film, or a single film of any of a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another.

The gate electrode 7b as used herein can be made of a polysilicon layer (a doped polysilicon layer) heavily doped with n-type impurity ions such as phosphorus (P) or p-type impurity ions such as boron (B), or made from refractory metal such as titanium (Ti) or tungsten (W), for example. The use of the p-type polysilicon layer for the gate electrode 7b can increase a gate threshold voltage. The use of the n-type polysilicon layer for the gate electrode 7b can enhance a speed of the switching operation.

The entire circumference along the bottom surface, the side surfaces on both sides, and the top surface of the gate electrode 7b is covered with the insulating film 6 in the cross-sectional side view in FIG. 3. An interlayer insulating film 8 is deposited on the top surface side of the gate electrode 7b with the insulating film 6 interposed. The gate electrode 7b is electrically connected to the gate runner 21 via the insulating film 6 and contact holes (gate contact holes) provided in the interlayer insulating film 8 on the front side and the back side of the sheet of FIG. 3.

The interlayer insulating film 8 as used herein is a borophosphosilicate glass film (a BPSG film), for example. The interlayer insulating film 8 may also be a single film of a phosphosilicate glass film (a PSG film), a non-doped silicon oxide film without containing phosphorus (P) or boron (B) which is referred to as a non-doped silicate glass (NSG) film, a borophosphosilicate glass film (a BSG film), or a silicon nitride film (a Si₃N₄ film), or a stacked film including some of the above films stacked on one another.

The drift layer 2 is provided with electric field relaxation regions 5a and 5b of p+-type so as to be in contact with the bottom surface and the side surfaces of the respective source trenches 10a and 10c. The electric field relaxation regions 5a and 5b have a higher impurity concentration than the respective base regions 3a to 3d. The electric field relaxation regions 5a and 5b relax an electric field concentrated on the gate insulating film 6 located at the bottom of the gate trench 10b so as to protect the gate insulating film 6 at the bottom of the gate trench 10b. The electric field relaxation regions 5a and 5b can be formed by implantation of impurity ions into the side surfaces and the bottom surface of the respective source trenches 10a and 10c after the source trenches 10a and 10c are formed.

The source region 4a and the base region 3a are in contact with the side surface on the left side of the source trench 10a with the electric field relaxation region 5a interposed. The source region 4b and the base region 3b are in contact with the side surface on the right side of the source trench 10a with the electric field relaxation region 5a interposed. The source region 4c and the base region 3c are in contact with the side surface on the left side of the source trench 10c with the electric field relaxation region 5b interposed. The source region 4d and the base region 3d are in contact with the side surface on the right side of the source trench 10b with the electric field relaxation region 5b interposed.

The insulating film 6 is provided along the bottom surface and the side surfaces on both sides of the respective source trenches 10a and 10c. The conductive layers 7a and 7c are buried inside the source trenches 10a and 10c respectively with the insulating film 6 interposed. The respective conductive layers 7a and 7c are made from the same material as the gate electrode 7b, and are made of a polysilicon layer heavily doped with n-type impurity ions or p-type impurity ions, for example. The entire circumference along the bottom surface, the side surfaces on both sides, and the top surface of the respective conductive layers 7a and 7c may be covered with the insulating film 6. This case leads the respective conductive layers 7a and 7c to have a floating potential. The insulating film 6 may be provided with contact holes so as to lead the respective conductive layers 7a and 7c to be connected to a source electrode 28. The respective conductive layers 7a and 7c in this case have the same potential as the source electrode 28.

The first main electrode (the source electrode) 28 is provided on the top surface side of the respective conductive layers 7a and 7c with the insulating film 6 interposed. The source electrode 28 is connected to the respective source regions 4a to 4d and the respective electric field relaxation regions 5a and 5b via contact holes (source contact holes) provided in the interlayer insulating film 8. The source electrode 28 may be made of an aluminum (Al) film or an aluminum-silicon (Al—Si) film, for example. The regions between the respective top surfaces of the source regions 4a to 4d and the electric field relaxation regions 5a and 5b and the source electrode 28 may be provided with a silicide layer including nickel silicide (NiSiₓ) so as to ensure an ohmic contact or a barrier metal layer including titanium nitride (TiN) or titanium (Ti).

A second main region (a drain region) 1 of n⁺-type having a higher impurity concentration than the drift layer 2 is deposited on the bottom surface side of the drift layer 2. The drain region 1 is made of a semiconductor substrate including SiC.

A second main electrode (a drain electrode) 11 is further deposited on the bottom surface side of the drain region 1. The drain electrode 11 as used herein can be a single film including gold (Au) or a metallic film including titanium (Ti), nickel (Ni), and Au stacked in this order, and may be further provided with a metallic film including molybdenum (Mo) or tungsten (W) stacked as a lowermost layer, for example. A silicide layer including nickel silicide (NiSiₓ), for example, may be provided between the drain region 1 and the drain electrode 11.

A plurality of trenches (trenches for resistance) 10d to 10g are provided at the upper part of the drift layer 2 toward the outer circumference of the active part 101 on the outer side of the source trench 10c. The respective trenches for resistance 10d to 10g do not serve as an active element but partly implement the internal resistance part 100 illustrated in FIG. 2. While FIG. 3 illustrates the case in which the four trenches for resistance 10d to 10g are provided, the number of the trenches for resistance is not limited to this case, and the present embodiment may include the single to three trenches for resistance, or may include five or more trenches for resistance.

A depth d3 of the respective trenches for resistance 10d to 10g is greater than the depth d2 of the gate trench 10b, and is substantially the same as the depth d1 of the respective source trenches 10a and 10c. The depth d3 of the respective trenches for resistance 10d to 10g may be different from the depth d1 of the respective source trenches 10a and 10c. The depth d3 of the respective trenches for resistance 10d to 10g may be shallower than the depth d1 of the respective source trenches 10a and 10c, and may be substantially the same as the depth d2 of the gate trench 10b.

A width w3 of the respective trenches for resistance 10d to 10g is substantially the same as the width w1 of the respective source trenches 10a and 10c and the width w2 of the gate trench 10b. The width w3 of the respective trenches for resistance 10d to 10g may be different from the width w1 of the respective source trenches 10a and 10c and the width w2 of the gate trench 10b. The intervals s2 between the trenches for resistance 10d to 10g next to each other are substantially the same as the intervals s1 between the respective source trenches 10a and 10c and the gate trench 10b. The intervals s2 between the trenches for resistance 10d to 10g next to each other may be different from the intervals s1 between the respective source trenches 10a and 10c and the gate trench 10b.

An electric field relaxation region 5c of p+-type is provided at the upper part of the drift layer 2 so as to be in contact with the bottom surface and the side surfaces of the respective trenches for resistance 10d to 10g. The electric field relaxation region 5c has a meandering shape in cross section across the left side of the trench for resistance 10d to the right side of the trench for resistance 10g in the cross-sectional view in FIG. 3.

Resistance layers 7d to 7g are buried in the trenches for resistance 10d to 10g respectively with the insulating film 6 interposed. The resistance layers 7d to 7g are made from the same material as the gate electrode 7b and the respective conductive layers 7a and 7c, and are made of a polysilicon layer heavily doped with n-type impurity ions or p-type impurity ions, for example. The entire circumference along the bottom surface, the side surfaces on both sides, and the top surface of the respective resistance layers 7d to 7g is covered with the insulating film 6. The positions at the upper ends of the resistance layers 7d to 7g buried in the source trenches 10d to 10g are located at substantially the same positions as the upper ends of the conductive layers 7a and 7c buried in the source trenches 10a and 10c and the position at the upper end of the gate electrode 7b buried in the gate trench 10b. The interlayer insulating film 8 is deposited on the top surface side of the respective resistance layers 7d to 7g.

A plurality of trenches (outer circumferential-side trenches) 10h and 10i are provided at the upper part of the drift layer 2 toward the outer circumference of the active part 101 on the outer side of the trench for resistance 10g. While FIG. 3 illustrates the case in which the two outer circumferential-side trenches 10h and 10i are provided, the number of the outer circumferential-side trenches may be determined as appropriate. The present embodiment may include the single to three outer circumferential-side trenches, or may include five or more outer circumferential-side trenches.

A depth d4 of the respective outer circumferential-side trenches 10h and 10i is greater than the depth d2 of the gate trench 10b, and is substantially the same as the depth d1 of the respective source trenches 10a and 10c and the depth d3 of the respective trenches for resistance 10d to 10g. A width w4 of the respective outer circumferential-side trenches 10h and 10i is substantially the same as the width w1 of the respective source trenches 10a and 10c, the width w2 of the gate trench 10b, and the width w3 of the respective trenches for resistance 10d to 10g. An interval s3 between the outer circumferential-side trenches 10h and 10i is substantially the same as the intervals s1 between the respective source trenches 10a and 10c and the gate trench 10b and the intervals s2 between the trenches for resistance 10d to 10g next to each other.

Conductive layers 7h and 7i are buried in the outer circumferential-side trenches 10h and 10i respectively with the insulating film 6 interposed. The conductive layers 7h and 7i are made from the same material as the gate electrode 7b, the respective conductive layers 7a and 7c, and the resistance layers 7d to 7g, and are made of a polysilicon layer heavily doped with n-type impurity ions or p-type impurity ions, for example. The entire circumference along the bottom surface, the side surfaces on both sides, and the top surface of the respective conductive layers 7h and 7i is covered with the insulating film 6. The gate runner 21 is deposited on the top surface side of the respective conductive layers 7h and 7i with the insulating film 6 interposed.

The terminal part 102 located on the outer circumferential side of the active part 101 is provided with a step 10j. A depth d5 of the step 10j is substantially the same as the depth d1 of the respective source trenches 10a and 10c, the depth d3 of the respective trenches for resistance 10d to 10g, and the depth d4 of the respective outer circumferential-side trenches 10h and 10i. The step 10j is provided with the p⁺-type electric field relaxation region 5c continuously from the active part 101. The region toward the outer circumference on the outer side of the end part of the electric field relaxation region 5c may be provided with a p-type region implementing a junction terminal extension (JTE) structure, or at least one of structures such as a guard ring, a field plate, and a reduced surface field (RESURF). The present embodiment includes a plurality of guard rings 5d to 5f of p⁺-type. The guard rings 5d to 5f are arranged separately from each other in a concentric ring-like state. The surface of the side wall part of the step 10j is provided with a wiring layer 29.

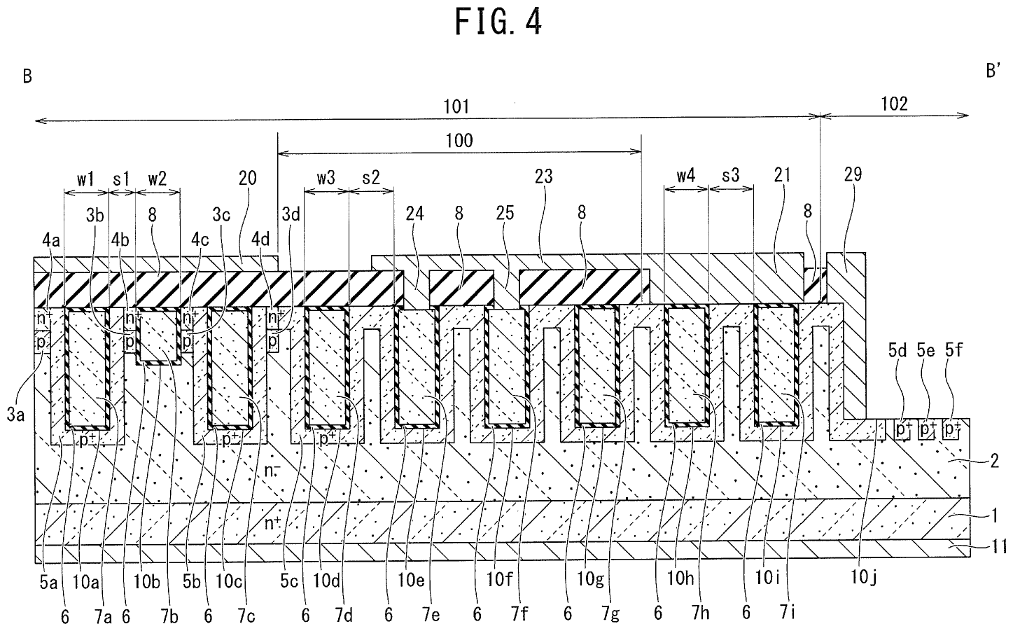

FIG. 4 is a schematic cross-sectional view taken along line B-B′ parallel to line A-A′ in FIG. 2. As illustrated in FIG. 4, the source trenches 10a and 10c, the gate trench 10b, the trenches for resistance 10d to 10g, and the outer circumferential-side trenches 10h and 10i are provided at the upper part of the drift layer 2. The gate pad 20 is provided separately from and at the same layer level as the source electrode 28 illustrated in FIG. 3 over the respective source trenches 10a and 10c and the gate trench 10b. The insulating film 6 and the interlayer insulating film 8 are provided with contact holes (contact holes for resistance) on the top surface side of the resistance layers 7e and 7f buried in the trenches for resistance 10e and 10f in the internal resistance part 100. The respective resistance layers 7e and 7f are connected to the gate runner 21 via contacts 24 and 25 provided in the contact holes for resistance and a wiring layer 23 provided on the top surface of the interlayer insulating film 8.

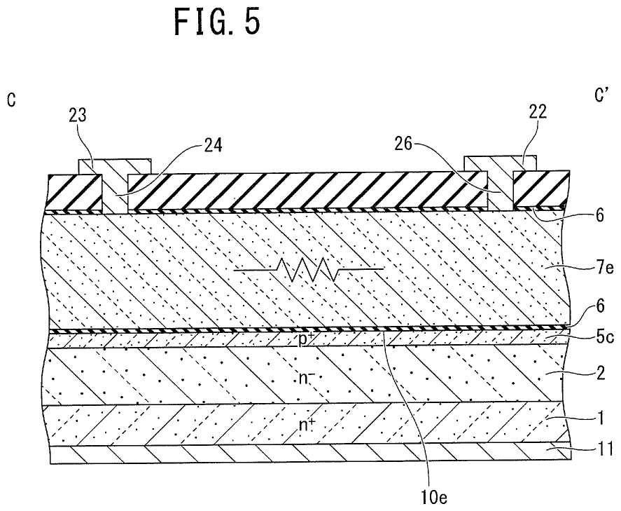

FIG. 5 is a schematic cross-sectional view taken along line C-C′ passing along the trench for resistance 10e in the direction perpendicular to line A-A′ and line B-B′ in FIG. 2. As illustrated in FIG. 5, the resistance layer 7e buried in the trench for resistance 10e is connected to the gate runner 21 illustrated in FIG. 2 via the contact 24 inside the contact hole (the contact hole for resistance) provided in the insulating film 6 and the interlayer insulating film 8 and via the wiring layer 23 provided on the top surface of the interlayer insulating film 8, and is connected to the gate pad 20 illustrated in FIG. 2 and FIG. 4 via a contact 26 inside the contact hole (the contact hole for resistance) provided in the insulating film 6 and the interlayer insulating film 8 and via a wiring layer 22 provided on the top surface of the interlayer insulating film 8. As schematically indicated by the circuit symbol for resistance in FIG. 5, the resistance layer 7e between the contact 24 and the contact 26 serves as a resistor.

As illustrated in FIG. 2, the resistance layer 7e buried in the trench for resistance 10e is connected to the wiring layer 23 via the contact 24, and is connected to the wiring layer 22 via the contact 26 separated from the bonding part of the contact 24 with a predetermined gap interposed. The resistance layer 7f buried in the trench for resistance 10f is connected to the wiring layer 23 via a contact 25, and is connected to the wiring layer 22 via a contact 27 separated from the contact 25 with a predetermined gap interposed. In other words, the resistance layer 7e between the contact 24 and the contact 26 and the resistance layer 7f between the contact 25 and the contact 27 in the internal resistance part 100 are connected in parallel so as to serve as a resistor.

A resistance value of the internal resistance part 100 can be adjusted as appropriate such that the positions of the contacts connected to the resistance layers 7d to 7g buried in the trenches for resistance 10d to 10g (namely, the length of the respective resistance layers 7d to 7g between the contacts) and the number of the resistance layers 7d to 7g connected in parallel to serve as a resistor are regulated. For example, the gap between the contact 24 and the contact 26 and the gap between the contact 25 and the contact 27 illustrated in FIG. 2 are increased, so as to increase the resistance value of the entire internal resistance part 100. The increase in the number of the resistance layers 7d to 7g connected in parallel can decrease the resistance value of the entire internal resistance part 100.

During the operation of the semiconductor device according to the first embodiment, when a positive voltage is applied to the drain electrode 11 while the source electrode 28 is used as an earth potential and a positive voltage of a threshold or greater is applied to the gate electrode 7b, an inversion layer (channel) is formed in the respective base regions 3b and 3c toward the side surfaces of the gate trench 10b so as to be in the turn-on state. The inversion layer is formed on the respective surfaces of the base regions 3b and 3c exposed to the side surfaces of the gate trench 10b that are the interfaces between the insulating film 6 and the respective base regions 3b and 3c at the positions at which the base regions 3b and 3b are opposed to the gate electrode 7. In the ON state, a current flows to the source electrode 28 from the drain electrode 11 via the drain region 1, the drift layer 2, the inversion layers of the base regions 3b and 3c, and the source regions 4b and 4c. When the voltage applied to the gate electrode 7b is less than the threshold, the semiconductor device is in the OFF state since no inversion layer is formed in the base region 3b or 3c, and no current flows to the source electrode 28 from the drain electrode 11.

The semiconductor device according to the first embodiment has the configuration including the active part 101 provided with the trenches in the entire region across the both ends of the active part 101, in which the resistance layers 7d to 7g buried in the trenches 10d to 10g for resistance extending across the both ends of the active part 101 implement the internal resistance part 100. This configuration can facilitate the inclusion of the gate resistance inside the device without increasing the extra manufacturing steps, as compared with the case in which the resistance element is formed on the top surface side of the semiconductor substrate.

Further, setting the depth d1 of the source trenches 10a and 10c, the depth d3 of the trenches for resistance 10d to 10g, and the depth d4 of the outer circumferential-side trenches 10h and 10i to substantially the same can further equalize the electric field in the active part 101, so as to avoid a local concentration of the electric field accordingly.

Further, setting the width w1 of the source trenches 10a and 10c, the width w2 of the gate trench 10b, the width w3 of the trenches for resistance 10d to 10g, and the width w4 of the outer circumferential-side trenches 10h and 10i to substantially the same can lead the trenches to be formed equally in the entire active part 101, so as to further equalize the electric field in the active part 101 to avoid a local concentration of the electric field accordingly.

Further, setting the interval s1 between the respective source trenches 10a and 10c and the gate trench 10b, the interval s2 between the trenches for resistance 10d to 10g next to each other, and the interval s3 between the outer circumferential-side trenches 10h and 10i to substantially the same can lead the trenches to be formed equally in the entire active part 101, so as to further equalize the electric field in the active part 101 to avoid a local concentration of the electric field accordingly.

Further, providing the electric field relaxation region 5c to be in contact with the bottom surface and the side surfaces of the respective trenches for resistance 10d to 10g and the bottom surface and the side surfaces of the outer circumferential-side trenches 10h and 10i leads to the same structure as the respective electric field relaxation regions 5a and 5c of the source trenches 10a and 10c, so as to further equalize the electric field in the active part 101 to avoid a local concentration of the electric field accordingly.

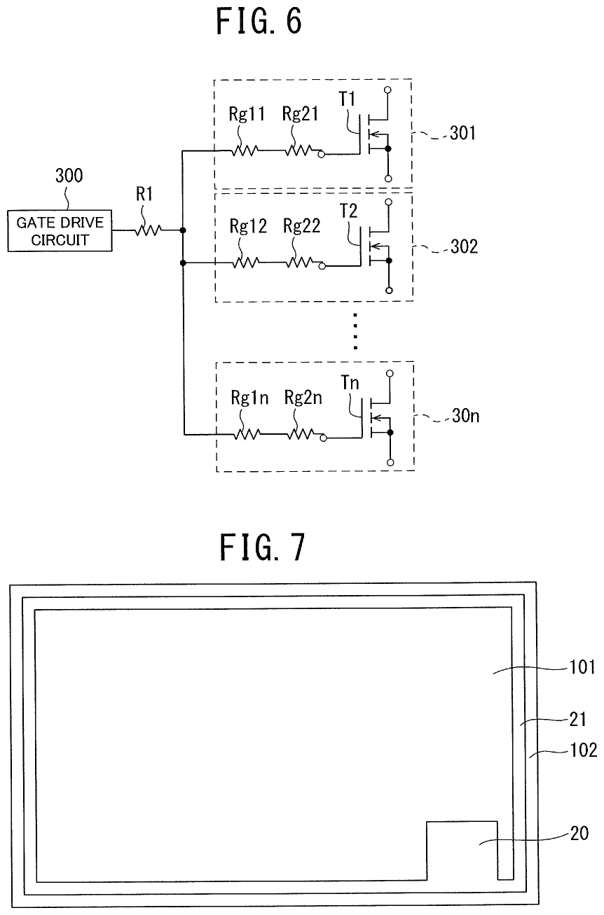

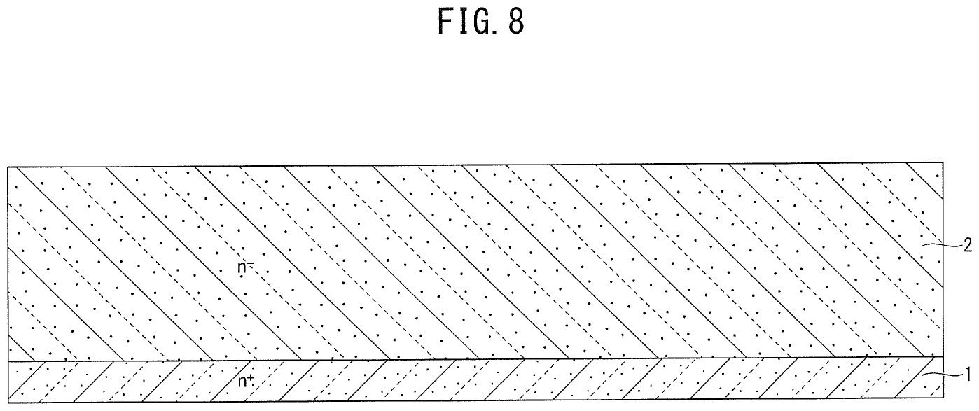

FIG. 6 is a circuit diagram illustrating an example of a semiconductor module according to the first embodiment. The semiconductor module according to the first embodiment includes a gate drive circuit 300, and a plurality of semiconductor chips 301, 302, . . . , 30n (n is an integer of three or greater) each having a gate electrically connected to the gate drive circuit 300. A wiring resistance R1 is connected between the gate drive circuit 300 and the respective gates of the semiconductor chips 301, 302, . . . , 30n. The semiconductor chips 301, 302, . . . , 30n each correspond to the semiconductor device according to the first embodiment illustrated in FIG. 1 to FIG. 5.

The semiconductor chip 301 includes a parasitic gate resistance Rg11 with one end connected to the wiring resistance R1, an inner gate resistance Rg21 with one end connected to the other end of the parasitic gate resistance Rg11, and a transistor T1 with the gate connected to the other end of the inner gate resistance Rg21. The semiconductor chip 302 includes a parasitic gate resistance Rg12 with one end connected to the wiring resistance R1, an inner gate resistance Rg22 with one end connected to the other end of the parasitic gate resistance Rg12, and a transistor T2 with the gate connected to the other end of the inner gate resistance Rg22. The semiconductor chip 30n includes a parasitic gate resistance Rg1n (n is an integer of three or greater) with one end connected to the wiring resistance R1, an inner gate resistance Rg2n (n is an integer of three or greater) with one end connected to the other end of the parasitic gate resistance Rg1n, and a transistor Tn (n is an integer of three or greater) with the gate connected to the other end of the inner gate resistance Rg2n.

The transistors T1, T2, . . . , Tn each correspond to the MOSFET that is the active element of the semiconductor device according to the first embodiment. The parasitic gate resistances Rg11, Rg12, . . . , Rg1n each correspond to the parasitic resistance of the gate electrode 7b of the semiconductor device according to the first embodiment. The inner gate resistances Rg21, Rg22, . . . , Rg2n each correspond to the internal resistance part 100 of the semiconductor device according to the first embodiment.

In the semiconductor module according to the first embodiment, the plural semiconductor chips 301, 302, . . . , 30n would be connected in parallel through which a small current flows so as to increase the entire amount of current, since the semiconductor chips including silicon carbide (SiC) have a low proportion of good quality as compared with semiconductor chips including silicon (Si). While the semiconductor chips 301, 302, . . . , 30n in this case need to be switched simultaneously, the inner gate resistance Rg21, Rg22, . . . , Rg2n adjusted to be increased more than the parasitic gate resistances Rg11, Rg21, . . . , Rg1n can reduce the imbalance between the semiconductor chips 301, 302, . . . , 30n upon the switching operation.

FIG. 7 is a view illustrating a semiconductor device of a comparative example. As illustrated in FIG. 7, the semiconductor device of the comparative example differs from the semiconductor device according to the first embodiment illustrated in FIG. 1 in not including the internal resistance part 100 between the gate pad 20 and the gate runner 21. The semiconductor device of the comparative example, if applied to the semiconductor chips 301, 302, . . . , 30n of the semiconductor module illustrated in FIG. 6, causes the imbalance between the semiconductor chips 301, 302, . . . , 30n upon the switching operation. The semiconductor device according to the first embodiment including the internal resistance part 100 can reduce the imbalance between the semiconductor chips 301, 302, . . . , 30n upon the switching operation.

<Method of Manufacturing Semiconductor Device>

An example of a method of manufacturing the semiconductor device according to the first embodiment is described below based on the cross-sectional view of FIG. 4. It should be understood that the method of manufacturing the semiconductor device described below is an example, and the semiconductor device can be manufactured by other methods including modified examples of this embodiment within the scope of the appended claims.

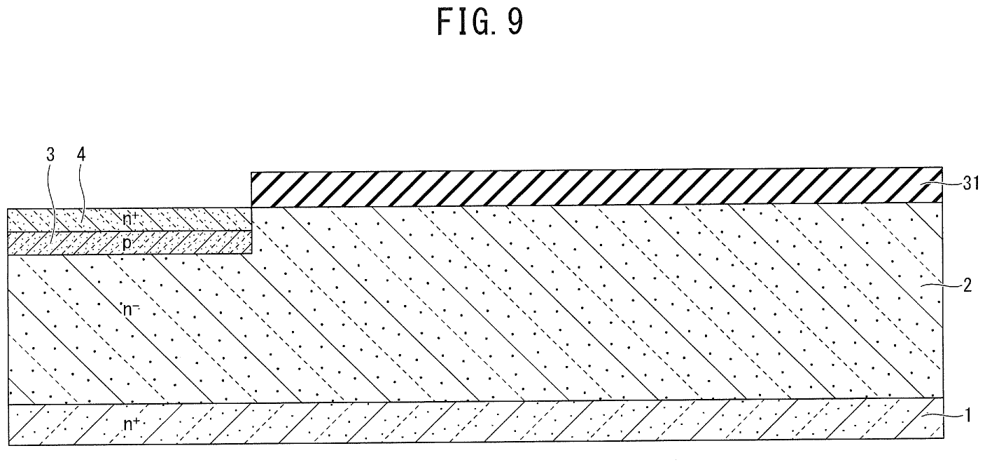

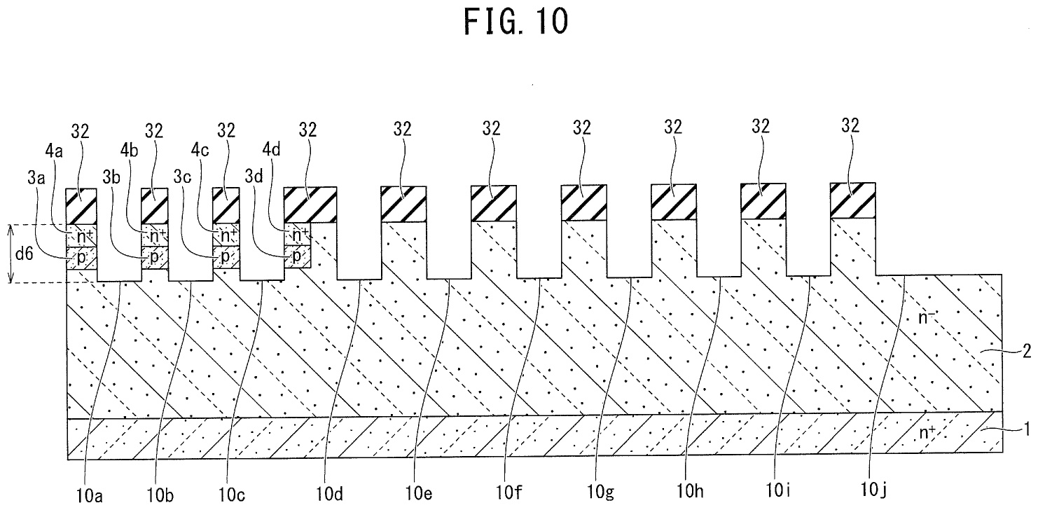

First, the n⁺-type semiconductor substrate 1 (refer to FIG. 9) including SiC doped with n-type impurity ions such as nitrogen (N) is prepared. Next, the n⁻-type drift layer 2 (refer to FIG. 9) including SiC doped with n-type impurity ions such as N and having a lower impurity concentration than the semiconductor substrate 1 is epitaxially grown on the top surface of the semiconductor substrate 1.

Next, a photoresist film 31 (refer to FIG. 9) is applied on the top surface of the drift layer 2, and is delineated by photolithography. Using the delineated photoresist film 31 as a mask for ion implantation, p-type impurity ions such as boron (B) or aluminum (Al) are selectively implanted into the drift layer 2 so as to form the p-type base region 3 (refer to FIG. 9) at the upper part of the drift layer 2 of the active part 101. Further, using the photoresist film 31 as a mask for ion implantation, n-type impurity ions such as phosphorus (P) or nitrogen (N) are selectively implanted into the drift layer 2 in a shallower projection range than the previous ion implantation of the p-type impurity ions so as to form the n⁺-type source region 4 at the upper part of the drift layer 2 of the active part 101, as illustrated in FIG. 9. The execution order of the implantation of the p-type impurity ions and the implantation of the n-type impurity ions is not limited to this case, and this implantation order may be inverted. The photoresist film 31 is then removed. Instead of the photoresist film 31, an oxide film may be used to be delineated so as to be used as the mask for ion implantation.

Next, a photoresist film 32 (refer to FIG. 10) is applied on the top surface of the drift layer 2, and is delineated by photolithography. Using the delineated photoresist film 32 as a mask for etching, the upper part of the drift layer 2 is selectively removed by dry etching such as reactive ion etching (RIE). This step selectively forms the source trenches 10a and 10c, the gate trench 10b, the trenches for resistance 10d to 10g, the outer circumferential-side trenches 10h and 10i, and the step 10j, as illustrated in FIG. 10.

The depth d6 of the source trenches 10a and 10c, the gate trench 10b, the trenches for resistance 10d to 10g, the outer circumferential-side trenches 10h and 10i, and the step 10j illustrated in FIG. 10 is common to the depth d2 of the gate trench 10b illustrated in FIG. 3 and FIG. 4, and is shallower than the depth d1 of the source trenches 10a and 10c, the depth d3 of the trenches for resistance 10d to 10g, the depth d4 of the outer circumferential-side trenches 10h and 10i, and the depth d5 of the step 10j illustrated in FIG. 3 and FIG. The source trenches 10a and 10c and the gate trench 10b divide the base region 3 into the base regions 3a to 3d, and divide the source region 4 into the source regions 4a to 4d. The photoresist film 32 is then removed. Instead of the photoresist film 32, an oxide film may be used to be delineated so as to be used as the mask for etching.

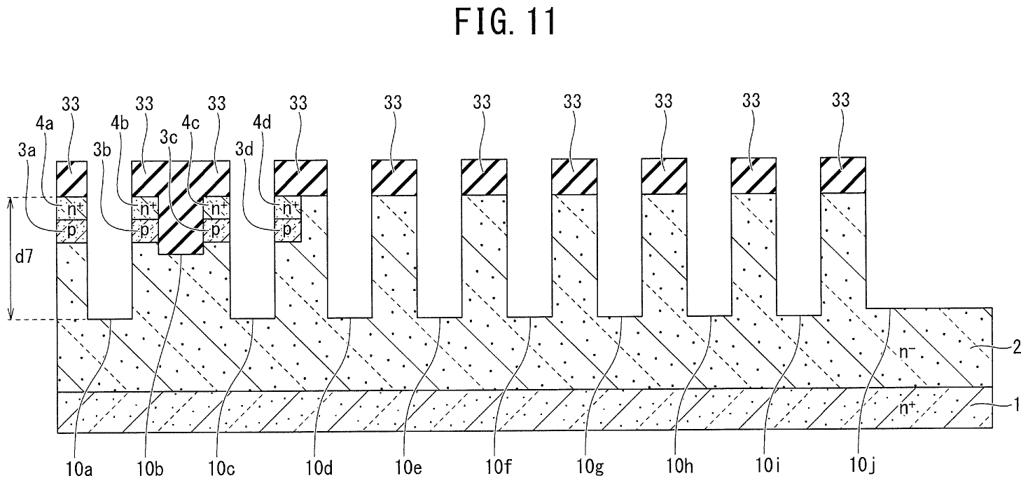

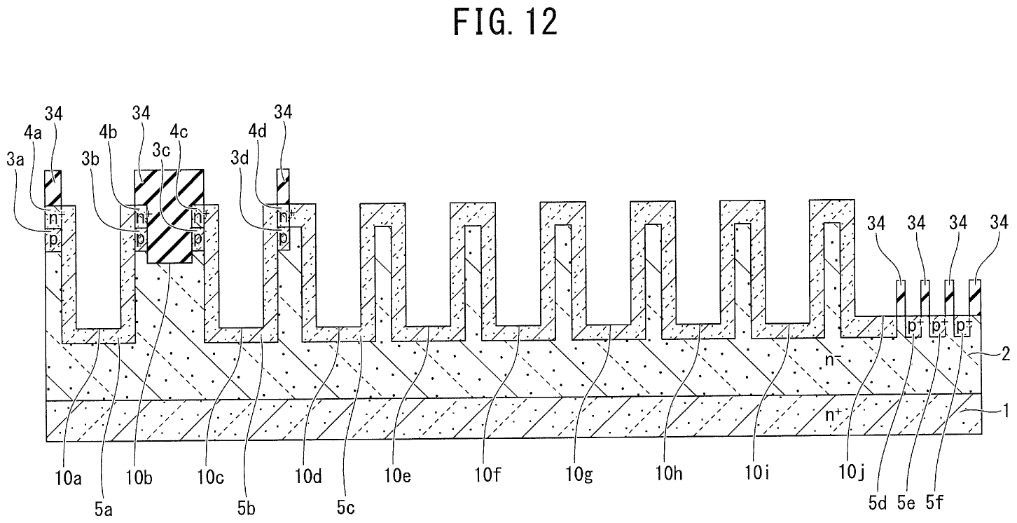

Next, a photoresist film 33 (refer to FIG. 11) is applied on the top surface of the drift layer 2, and is delineated by photolithography. Using the delineated photoresist film 33 as a mask for etching, the upper part of the drift layer 2 is selectively removed by dry etching such as reactive ion etching (RIE). This step leads the source trenches 10a and 10c, the trenches for resistance 10d to 10g, the outer circumferential-side trenches 10h and 10i, and the step 10j other than the gate trench 10b to be further dug so as to have a depth d7, as illustrated in FIG. 11.

The depth d7 of the source trenches 10a and 10c, the trenches for resistance 10d to 10g, the outer circumferential-side trenches 10h and 10i, and the step 10j illustrated in FIG. 11 is substantially the same as the depth d1 of the source trenches 10a and 10c, the depth d3 of the trenches for resistance 10d to 10g, the depth d4 of the outer circumferential-side trenches 10h and 10i, and the depth d5 of the step 10j illustrated in FIG. 3 and FIG. 4. The photoresist film 33 is then removed. Instead of the photoresist film 33, an oxide film may be used to be delineated so as to be used as the mask for etching.

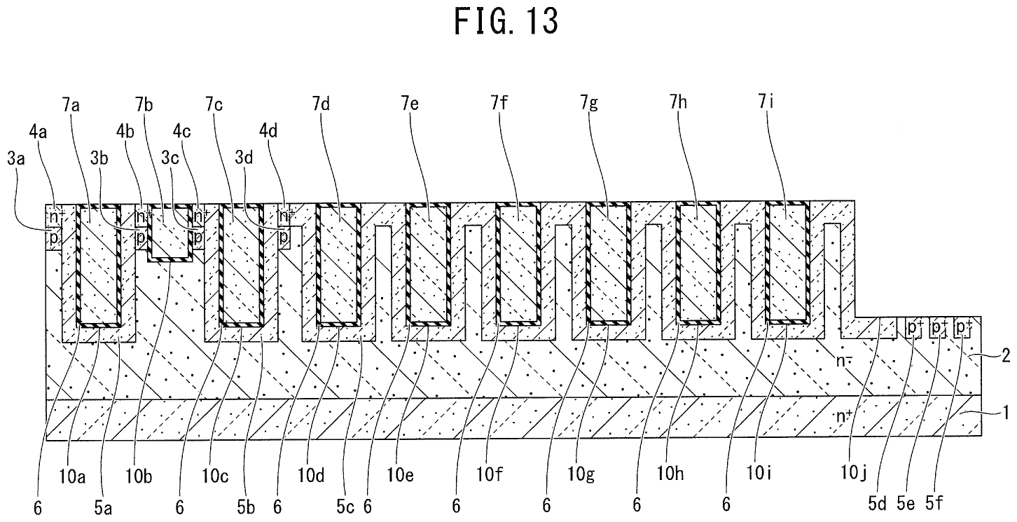

Next, a photoresist film 34 (refer to FIG. 12) is applied on the top surface of the drift layer 2, and is delineated by photolithography. Using the delineated photoresist film 34 as a mask for ion implantation, p-type impurity ions such as boron (B) or aluminum (Al) are implanted into the bottom surface and the side surfaces of each of the source trenches 10a and 10c, the trenches for resistance 10d to 10g, the outer circumferential-side trenches 10h and 10i, and the step 10j. This step forms the p⁺-type electric field relaxation regions 5a to 5c and the p⁺-type guard rings 5d to 5f at the upper part of the drift layer 2, as illustrated in FIG. 12.

The ion implantation for forming the p⁺-type electric field relaxation regions 5a to 5c and the p⁺-type guard rings 5d to 5f may be executed by the two separated steps in the inclined directions each having an angle with respect to the depth direction of the source trenches 10a and 10c, the trenches for resistance 10d to 10g, the outer circumferential-side trenches 10h and 10i, and the step 10j in the clockwise direction and the counterclockwise direction. Alternatively, when the respective side walls of the source trenches 10a and 10c, the trenches for resistance 10d to 10g, the outer circumferential-side trenches 10h and 10i, and the step 10j have a tapered shape, the execution of the single ion implantation in the vertical direction can form the p⁺-type electric field relaxation regions 5a to 5c and the p⁺-type guard rings 5d to 5f. Alternatively, the execution of the single ion implantation can form the p⁺-type electric field relaxation regions 5a to 5c and the p⁺-type guard rings 5d to 5f while taking account of the variation in angle of the ion implantation. The photoresist film 34 is then removed. Instead of the photoresist film 34, an oxide film may be used to be delineated so as to be used as the mask for etching.

Next, heat treatment (activation annealing) is executed so as to collectively activate the p-type impurity ions and the n-type impurity ions implanted into the p-type base regions 3a to 3d, the n⁺-type source regions 4a to 4d, the p⁺-type electric field relaxation regions 5a to 5c, and the p⁺-type guard rings 5d to 5f. The heat treatment (the activation annealing) may be executed independently for each ion implantation.

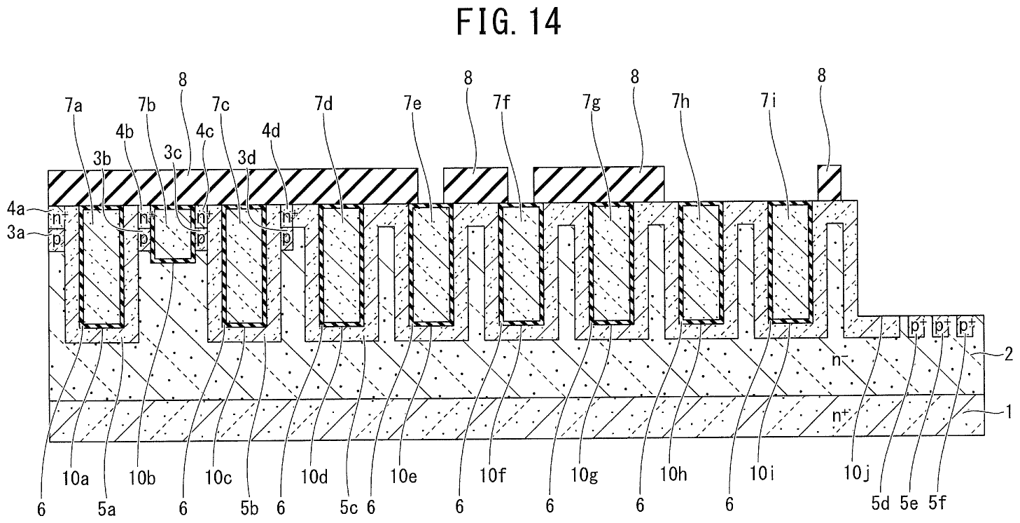

Next, the insulating film 6 (refer to FIG. 13) is formed on the bottom surface and the side surfaces of each of the source trenches 10a and 10c, the gate trench 10b, the trenches for resistance 10d to 10g, and the outer circumferential-side trenches 10h and 10i by a thermal oxidation method or a CVD method, for example. Next, a polysilicon layer (a doped polysilicon layer) heavily doped with n-type impurity ions or p-type impurity ions is deposited so as to fill the inside of each of the source trenches 10a and 10c, the gate trench 10b, the trenches for resistance 10d to 10g, and the outer circumferential-side trenches 10h and 10i. Next, a part of the polysilicon layer and a part of the insulating film 6 are selectively removed by photolithography and dry etching. This step forms the insulated gate electrode structure (6, 7b) (refer to FIG. 13) including the insulating film 6 as a gate insulating film and the gate electrode 7b buried in the gate trench 10b. The conductive layers 7a and 7c are buried in the source trenches 10a and 10c with the insulating film 6 interposed. The resistance layers 7d to 7g are buried in the trenches for resistance 10d to 10g with the insulating film 6 interposed. The conductive layers 7h and 7i are buried in the outer circumferential-side trenches 10h and 10i with the insulating film 6 interposed.

Next, the insulating film 6 is selectively formed further on the top surface of the polysilicon layer buried in the source trenches 10a and 10c, the gate trench 10b, the trenches for resistance 10d to 10g, and the outer circumferential-side trenches 10h and 10i by the thermal oxidation method or the CVD method, for example. This step leads the top surface of the gate electrode 7b buried in the gate trench 10b, the respective top surfaces of the conductive layers 7a and 7c buried in the source trenches 10a and 10c, the respective top surfaces of the resistance layers 7d to 7g buried in the trenches for resistance 10d to 10g, and the respective top surfaces of the conductive layers 7h and 7i buried in the outer circumferential-side trenches 10h and 10i to be covered with the insulating film 6, as illustrated in FIG. 13.

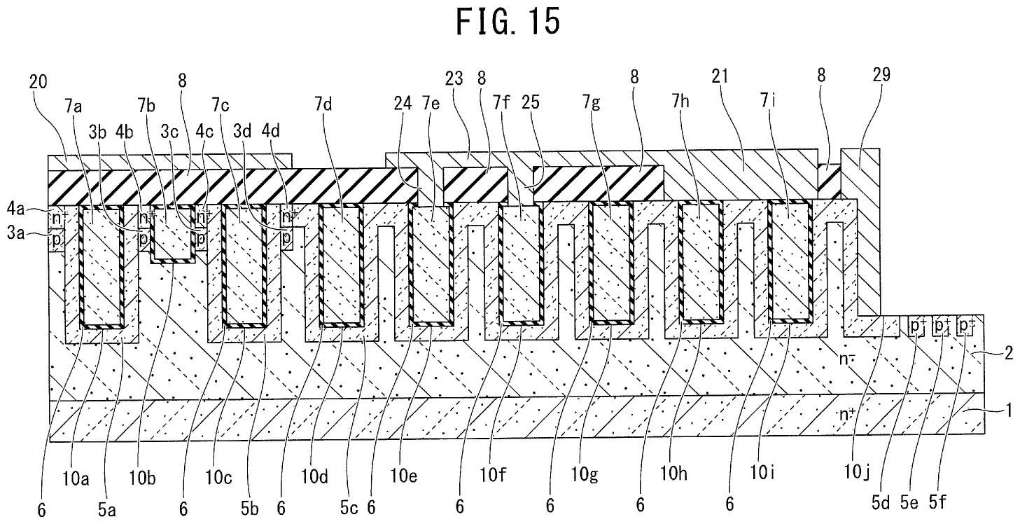

Next, the interlayer insulating film 8 (refer to FIG. 14) is deposited on the top surface of the insulated gate electrode structure (6, 7b) by the CVD method, for example. A part of the interlayer insulating film 8 is then selectively removed by photolithography and dry etching. This step forms the contact holes for resistance in the interlayer insulating film 8 so as to expose the top surfaces of the resistance layers 7e and 7f, as illustrated in FIG. 14. At this point, the interlayer insulating film 8 is further provided with a gate contact hole to which the top surface of the gate electrode 7b is exposed and source contact holes to which the respective top surfaces of the source regions 4a to 4d and the electric field relaxation regions 5a and 5b are exposed.

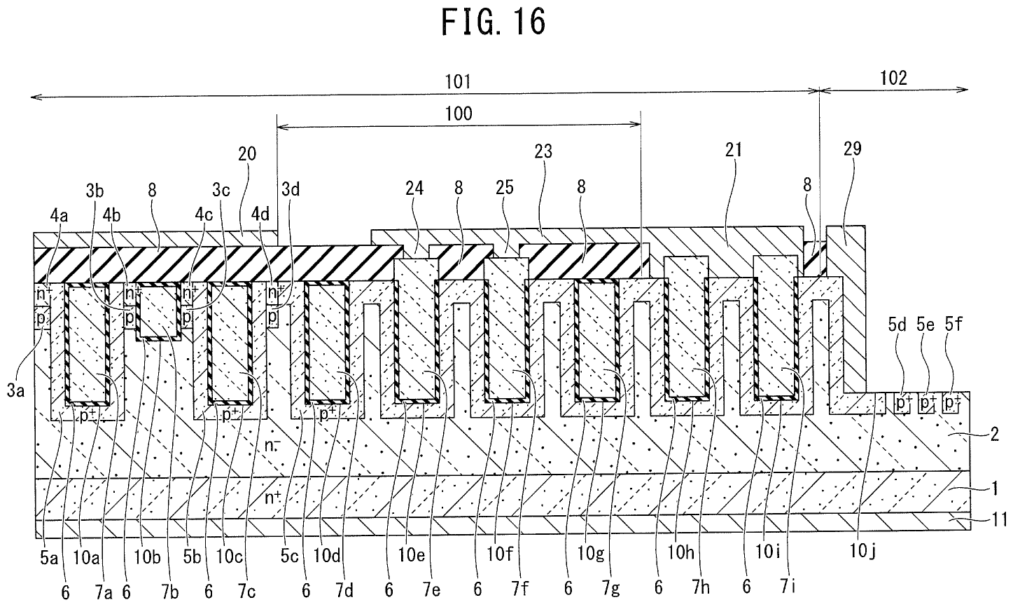

Next, a metal layer is deposited by a sputtering method or a vapor deposition method, for example. The metal layer is then delineated by photolithography and RIE. This step forms the source electrode 28 (refer to FIG. 3), the gate pad 20, the gate runner 21, the wiring layers 22 and 23 (refer to FIG. 2), the contacts 24 and 25, and the like that each are a part of the metal layer, as illustrated in FIG. 15. The gate runner 21 is electrically connected to the resistance layers 7e and 7f via the contacts 24 and 25 inside the contact holes for resistance of the interlayer insulating film 8 and the wiring layer 23. The gate runner 21 is electrically connected to the gate electrode 7b via the gate contact holes in the interlayer insulating film 8. The source electrode 28 is electrically connected to the source regions 4a to 4d and the electric field relaxation regions 5a and 5b via the source contact holes in the interlayer insulating film 8.

Next, the semiconductor substrate 1 is subjected to grinding from the bottom surface side and the thickness is adjusted by grinding or chemical mechanical polishing (CMP) so as to serve as a drain region. Thereafter, the drain electrode 11 (refer to FIG. 2) including gold (Au) is formed on the entire bottom surface of the drain region 1 by the sputtering method or the vapor deposition method, for example. The semiconductor device as illustrated in FIG. 2 is thus completed.

### Second Embodiment

A semiconductor device according to a second embodiment differs from the semiconductor device according to the first embodiment illustrated in FIG. 4 in that the respective upper parts of the resistance layers 7e and 7f buried in the trenches for resistance 10e and 10f and the conductive layers 7h and 7i buried in the outer circumferential-side trenches 10h and 10i project upward from the trenches for resistance 10e and 10f and the outer circumferential-side trenches 10h and 10i, as illustrated in FIG. 16. The respective upper ends of the resistance layers 7e and 7f and the conductive layers 7h and 7i are located at a higher position than the respective upper ends of the conductive layers 7a and 7c and the gate electrode 7b. The other configurations of the semiconductor device according to the second embodiment are substantially the same as those of the semiconductor device according to the first embodiment, and overlapping explanations are not repeated below.

The second embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the second embodiment has the configuration in which the respective upper parts of the resistance layers 7e and 7f buried in the trenches for resistance 10e and 10f and the conductive layers 7h and 7i buried in the outer circumferential-side trenches 10h and 10i project upward from the trenches for resistance 10e and 10f and the outer circumferential-side trenches 10h and 10i, so as to stabilize the manufacturing process.

### Third Embodiment

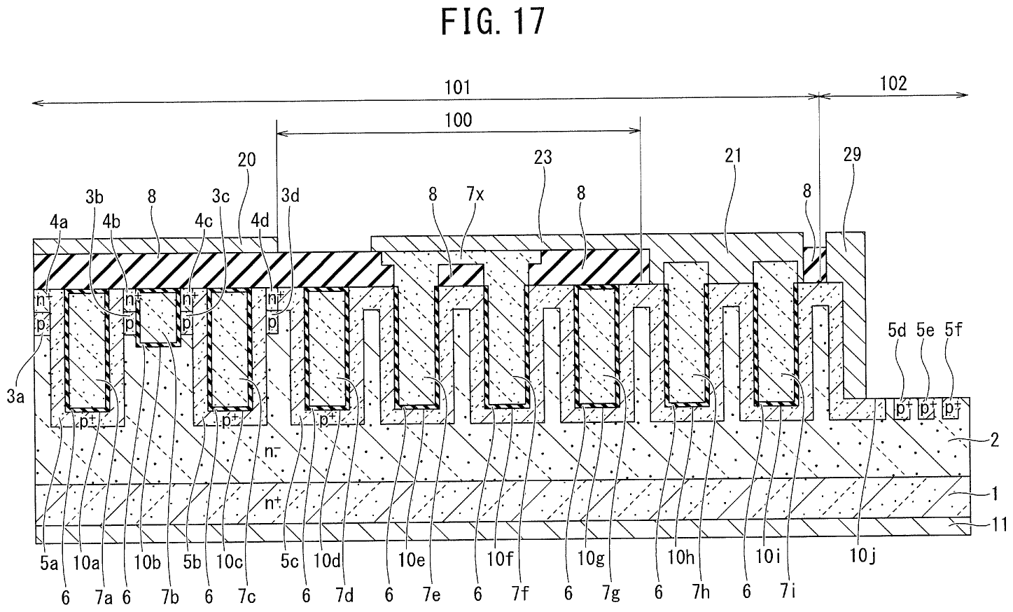

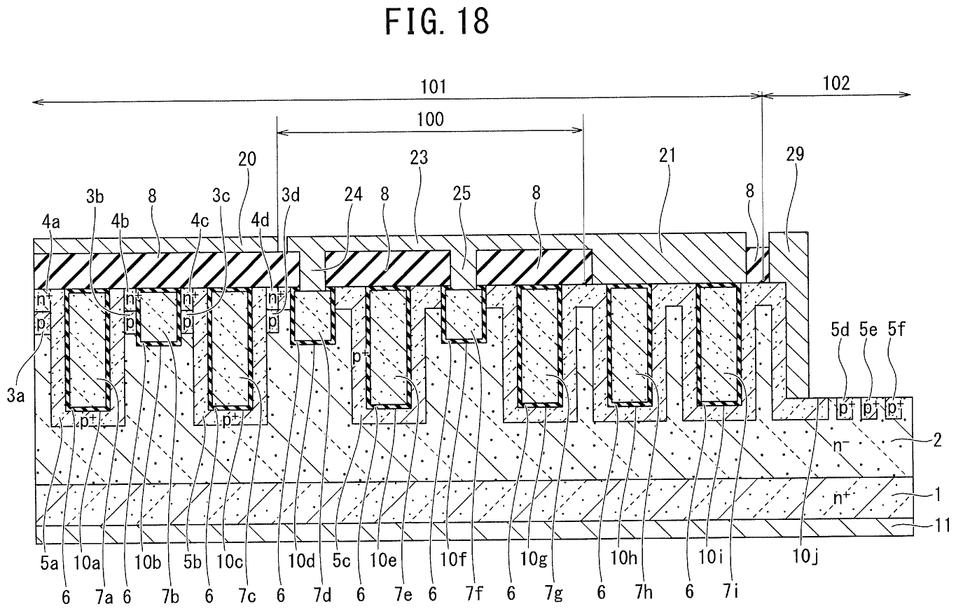

A semiconductor device according to a third embodiment differs from the semiconductor device according to the first embodiment illustrated in FIG. 4 in that the respective upper parts of the resistance layers 7e and 7f buried in the trenches for resistance 10e and 10f and the conductive layers 7h and 7i buried in the outer circumferential-side trenches 10h and 10i project upward from the trenches for resistance 10e and 10f and the outer circumferential-side trenches 10h and 10i, as illustrated in FIG. 17, as in the case of the semiconductor device according to the second embodiment illustrated in FIG. 16.

The semiconductor device according to the third embodiment further differs from the semiconductor device according to the first embodiment illustrated in FIG. 4 in that the resistance layers 7e and 7f buried in the trenches for resistance 10e and 10f are connected to each other via a connection part 7x made of a polysilicon layer, as illustrated in FIG. 17. The other configurations of the semiconductor device according to the third embodiment are substantially the same as those of the semiconductor device according to the first embodiment, and overlapping explanations are not repeated below.

The third embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the third embodiment has the configuration in which the respective upper parts of the resistance layers 7e and 7f buried in the trenches for resistance 10e and 10f and the conductive layers 7h and 7i buried in the outer circumferential-side trenches 10h and 10i project upward from the trenches for resistance 10e and 10f and the outer circumferential-side trenches 10h and 10i, and the resistance layers 7e and 7f are connected to each other via the connection part 7x, so as to stabilize the manufacturing process.

### Fourth Embodiment

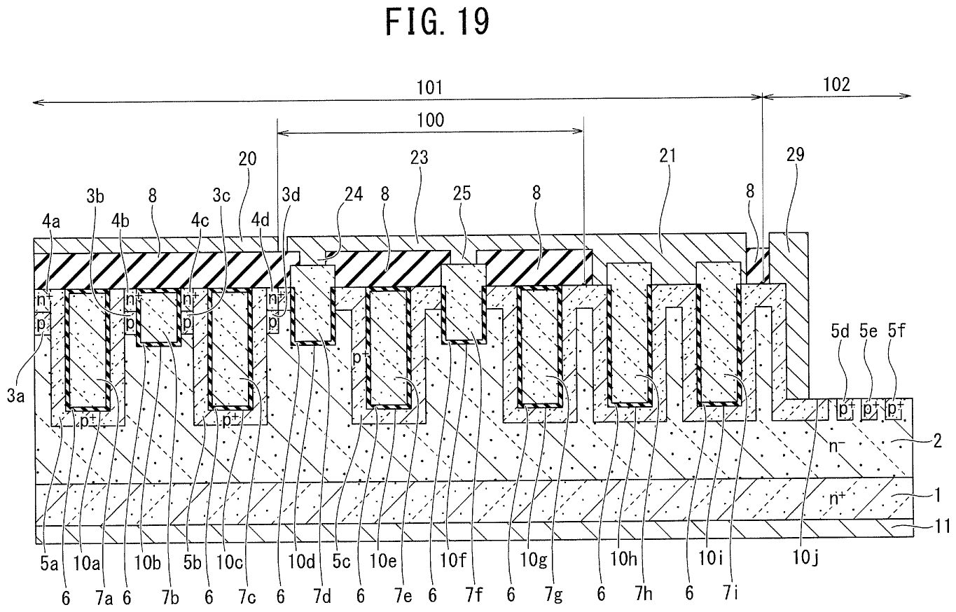

A semiconductor device according to a fourth embodiment differs from the semiconductor device according to the first embodiment illustrated in FIG. 4 in that the depth of the respective trenches for resistance 10d and 10f is different from the depth of the respective trenches for resistance 10e and 10g, as illustrated in FIG. 18. The depth of the respective trenches for resistance 10d and 10f is shallower than the depth of the respective trenches for resistance 10e and 10g, and is substantially the same as the depth of the gate trench 10b. The resistance layers 7d and 7f buried in the trenches for resistance 10d and 10f are connected to the wiring layer 23 via the contacts 24 and 25. The other configurations of the semiconductor device according to the fourth embodiment are substantially the same as those of the semiconductor device according to the first embodiment, and overlapping explanations are not repeated below.

The fourth embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the fourth embodiment has the configuration in which the depth of the respective trenches for resistance 10d and 10f is different from the depth of the respective trenches for resistance 10e and 10g, which is the same as the unit structure including the source trench 10a and the gate trench 10b in the active part 101, so as to further equalize the electric field in the active part 101, avoiding a local concentration of the electric field accordingly.

### Fifth Embodiment

A semiconductor device according to a fifth embodiment differs from the semiconductor device according to the first embodiment illustrated in FIG. 4 in that the depth of the respective trenches for resistance 10d and 10f is different from the depth of the respective trenches for resistance 10e and 10g, as illustrated in FIG. 19, as in the case of the semiconductor device according to the fourth embodiment illustrated in FIG. 18.

The semiconductor device according to the fifth embodiment further differs from the semiconductor device according to the first embodiment illustrated in FIG. 4 in that the respective upper parts of the resistance layers 7d and 7f buried in the trenches for resistance 10d and 10f and the conductive layers 7h and 7i buried in the outer circumferential-side trenches 10h and 10i project upward from the trenches for resistance 10d and 10f and the outer circumferential-side trenches 10h and 10i, as illustrated in FIG. 19. The other configurations of the semiconductor device according to the fifth embodiment are substantially the same as those of the semiconductor device according to the first embodiment, and overlapping explanations are not repeated below.

The fifth embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the fifth embodiment has the configuration in which the depth of the respective trenches for resistance 10d and 10f is different from the depth of the respective trenches for resistance 10e and 10g, which is the same as the structure including the gate trench 10b and the respective source trenches 10a and 10c in the active part 101, so as to further equalize the electric field in the active part 101, avoiding a local concentration of the electric field accordingly. Further, the fifth embodiment has the configuration in which the respective upper parts of the resistance layers 7d and 7f buried in the trenches for resistance 10d and 10f and the conductive layers 7h and 7i buried in the outer circumferential-side trenches 10h and 10i project upward from the trenches for resistance 10d and 10f and the outer circumferential-side trenches 10h and 10i, so as to stabilize the manufacturing process.

### Sixth Embodiment

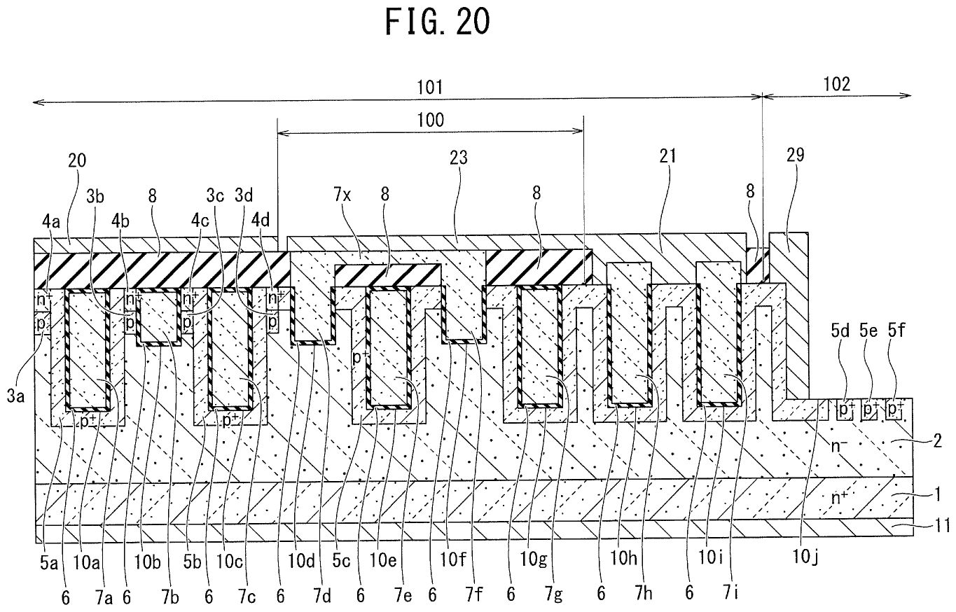

A semiconductor device according to a sixth embodiment differs from the semiconductor device according to the first embodiment illustrated in FIG. 4 in that the depth of the respective trenches for resistance 10d and 10f is different from the depth of the respective trenches for resistance 10e and 10g, and in that the respective upper parts of the resistance layers 7d and 7f buried in the trenches for resistance 10d and 10f and the conductive layers 7h and 7i buried in the outer circumferential-side trenches 10h and 10i project upward from the trenches for resistance 10d and 10f and the outer circumferential-side trenches 10h and 10i, as illustrated in FIG. 20, as in the case of the semiconductor device according to the fifth embodiment illustrated in FIG. 19.

The semiconductor device according to the sixth embodiment further differs from the semiconductor device according to the first embodiment illustrated in FIG. 4 in that the upper parts of the resistance layers 7d and 7f buried in the trenches for resistance 10d and 10f are connected to each other via the connection part 7x made of a polysilicon layer, as illustrated in FIG. 20. The other configurations of the semiconductor device according to the sixth embodiment are substantially the same as those of the semiconductor device according to the first embodiment, and overlapping explanations are not repeated below.

The sixth embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the sixth embodiment has the configuration in which the depth of the respective trenches for resistance 10d and 10f is different from the depth of the respective trenches for resistance 10e and 10g, which is the same as the structure including the gate trench 10b and the respective source trenches 10a and 10c in the active part 101, so as to further equalize the electric field in the active part 101, avoiding a local concentration of the electric field accordingly. Further, the sixth embodiment has the configuration in which the respective upper parts of the resistance layers 7d and 7f buried in the trenches for resistance 10d and 10f and the conductive layers 7h and 7i buried in the outer circumferential-side trenches 10h and 10i project upward from the trenches for resistance 10d and 10f and the outer circumferential-side trenches 10h and 10i, and in which the resistance layers 7d and 7f are connected to each other via the connection part 7x, so as to stabilize the manufacturing process.

### Seventh Embodiment

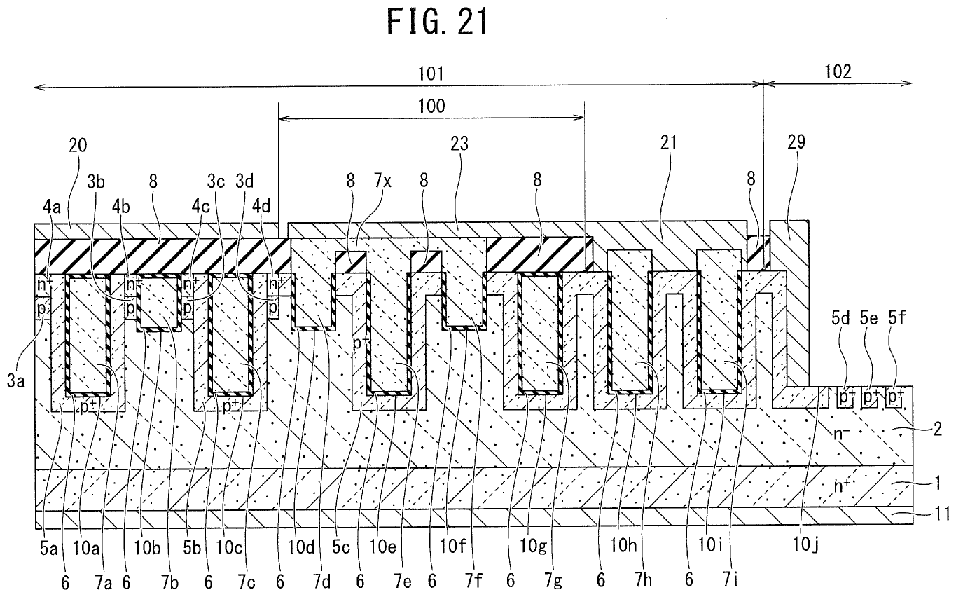

A semiconductor device according to a seventh embodiment differs from the semiconductor device according to the first embodiment illustrated in FIG. 4 in that the depth of the respective trenches for resistance 10d and 10f is different from the depth of the respective trenches for resistance 10e and 10g, in that the respective upper parts of the resistance layers 7d and 7f buried in the trenches for resistance 10d and 10f and the conductive layers 7h and 7i buried in the outer circumferential-side trenches 10h and 10i project upward from the trenches for resistance 10d and 10f and the outer circumferential-side trenches 10h and 10i, and in that the upper parts of the resistance layers 7d and 7f buried in the trenches for resistance 10d and 10f are connected to each other via the connection part 7x made of a polysilicon layer, as illustrated in FIG. 21, as in the case of the semiconductor device according to the sixth embodiment illustrated in FIG. 20.

The semiconductor device according to the seventh embodiment further differs from the semiconductor device according to the first embodiment illustrated in FIG. 4 in that the upper part of the resistance layer 7e buried in the trench for resistance 10e projects upward from the upper end of the trench for resistance 10e so as to be connected to the connection part 7x, as illustrated in FIG. 21. The other configurations of the semiconductor device according to the seventh embodiment are substantially the same as those of the semiconductor device according to the first embodiment, and overlapping explanations are not repeated below.

The seventh embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the seventh embodiment has the configuration in which the depth of the respective trenches for resistance 10d and 10f is different from the depth of the respective trenches for resistance 10e and 10g, which is the same as the structure including the gate trench 10b and the respective source trenches 10a and 10c in the active part 101, so as to further equalize the electric field in the active part 101, avoiding a local concentration of the electric field accordingly. Further, the seventh embodiment has the configuration in which the respective upper parts of the resistance layers 7d to 7f buried in the trenches for resistance 10d to 10f and the conductive layers 7h and 7i buried in the outer circumferential-side trenches 10h and 10i project upward from the trenches for resistance 10d to 10f and the outer circumferential-side trenches 10h and 10i, and in which the resistance layers 7d to 7f are connected to each other via the connection part 7x, so as to stabilize the manufacturing process.

### Eighth Embodiment

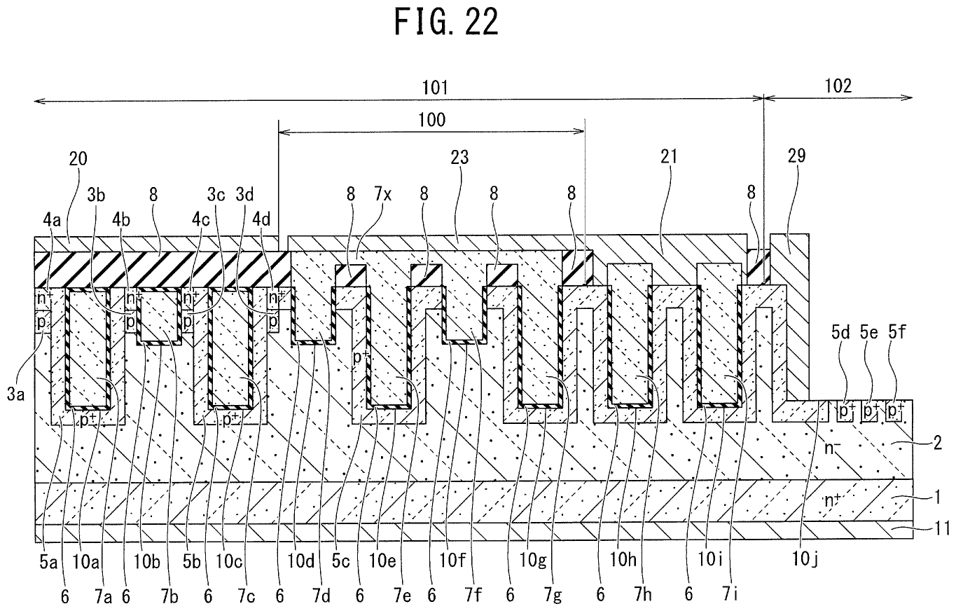

A semiconductor device according to an eighth embodiment differs from the semiconductor device according to the first embodiment illustrated in FIG. 4 in that the depth of the respective trenches for resistance 10d and 10f is different from the depth of the respective trenches for resistance 10e and 10g, in that the respective upper parts of the resistance layers 7d and 7f buried in the trenches for resistance 10d and 10f and the conductive layers 7h and 7i buried in the outer circumferential-side trenches 10h and 10i project upward from the trenches for resistance 10d and 10f and the outer circumferential-side trenches 10h and 10i, and in that the upper parts of the resistance layers 7d to 7f buried in the trenches for resistance 10d to 10f are connected to each other via the connection part 7x made of a polysilicon layer, as illustrated in FIG. 22, as in the case of the semiconductor device according to the seventh embodiment illustrated in FIG. 21.

The semiconductor device according to the eighth embodiment further differs from the semiconductor device according to the first embodiment illustrated in FIG. 4 in that the upper part of the resistance layer 7g buried in the trench for resistance 10g projects upward from the upper end of the trench for resistance 10g so as to be connected to the connection part 7x, as illustrated in FIG. 22. The other configurations of the semiconductor device according to the eighth embodiment are substantially the same as those of the semiconductor device according to the first embodiment, and overlapping explanations are not repeated below.

The eighth embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the eighth embodiment has the configuration in which the depth of the respective trenches for resistance 10d and 10f is different from the depth of the respective trenches for resistance 10e and 10g, which is the same as the structure including the gate trench 10b and the respective source trenches 10a and 10c in the active part 101, so as to further equalize the electric field in the active part 101, avoiding a local concentration of the electric field accordingly. Further, the eighth embodiment has the configuration in which the respective upper parts of the resistance layers 7d to 7g buried in the trenches for resistance 10d to 10g and the conductive layers 7h and 7i buried in the outer circumferential-side trenches 10h and 10i project upward from the trenches for resistance 10d to 10g and the outer circumferential-side trenches 10h and 10i, and in which the resistance layers 7d to 7g are connected to each other via the connection part 7x, so as to stabilize the manufacturing process.

### Ninth Embodiment

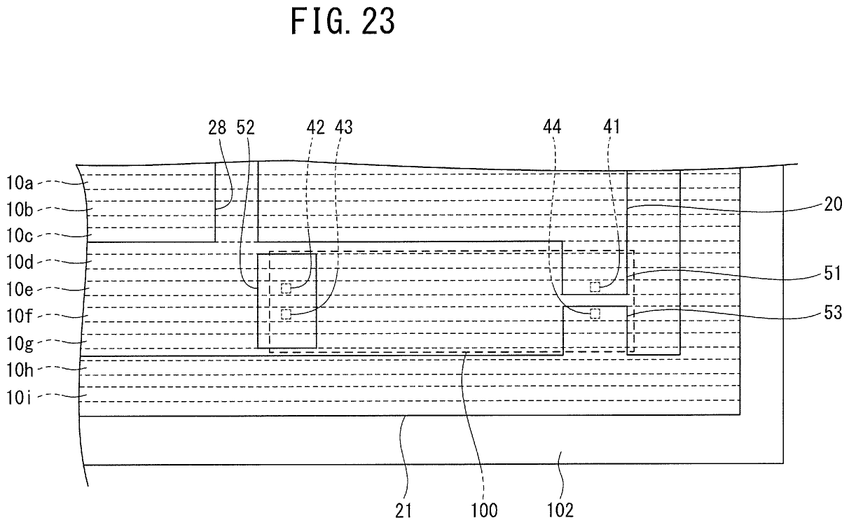

A semiconductor device according to a ninth embodiment differs from the semiconductor device according to the first embodiment illustrated in FIG. 2 in that the resistance layers 7e and 7f buried in the trenches for resistance 10e and 10f of the internal resistance part 100 are connected in series, as illustrated in FIG. 23. A wiring layer 51 is connected to the gate pad 20. The resistance layer 7e buried in the trench for resistance 10e (refer to FIG. 3 and FIG. 4) is connected to the wiring layer 51 via a contact 41. A wiring layer 52 is connected to the resistance layer 7e buried in the trench for resistance 10e via a contact 42 separately from the contact 41 with a predetermined gap. The resistance layer 7f buried in the trench for resistance 10f (refer to FIG. 3 and FIG. 4) is connected to the wiring layer 52 via a contact 43. A wiring layer 53 is connected to the resistance layer 7f buried in the trench for resistance 10f via a contact 44 separately from the contact 43 with a predetermined gap. The gate runner 21 is connected to the wiring layer 53.

The resistor in the internal resistance part 100 is implemented by the series connection between the resistance layer 7e buried in the trench for resistance 10e between the respective contacts 41 and 42 and the resistance layer 7f buried in the trench for resistance 10f between the respective contacts 43 and 44 so as to form a C-shaped current path in the planar pattern. The other configurations of the semiconductor device according to the ninth embodiment are substantially the same as those of the semiconductor device according to the first embodiment, and overlapping explanations are not repeated below.

The ninth embodiment includes the internal resistance part 100 implemented by the resistance layers 7d to 7g buried in the trenches for resistance 10d to 10g extending across the both ends of the active part 101, as in the case of the first embodiment, so as to facilitate the inclusion of the gate resistance inside the semiconductor device.

Further, the ninth embodiment having the configuration in which the resistance layers 7e and 7f are connected in series, can increase the resistance value of the internal resistance part 100 without the size of the internal resistance part 100 increased, so as to improve the flexibility of choice of the resistance value of the internal resistance part 100. The present embodiment may have a configuration in which three or more resistance layers are folded back so as to be further connected in series.

### Tenth Embodiment

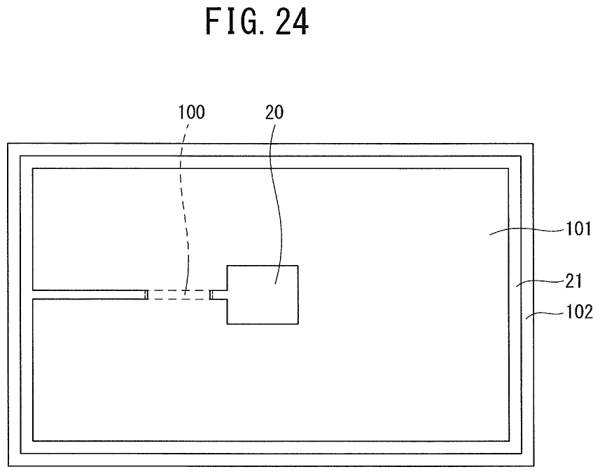

A semiconductor device according to a tenth embodiment differs from the semiconductor device according to the first embodiment illustrated in FIG. 1 in the arranged position of the gate pad 20, as illustrated in FIG. 24. The gate pad 20 is arranged in the middle of the active part 101. The internal resistance part 100 is connected between the gate pad 20 and the gate runner 21. The other configurations of the semiconductor device according to the tenth embodiment are substantially the same as those of the semiconductor device according to the first embodiment, and overlapping explanations are not repeated below.

The tenth embodiment has the configuration in which the gate pad 20 and the internal resistance part 100 are arranged at the positions different from those of the first embodiment, but the internal resistance part 100 is still implemented by the resistance layers buried in the trenches for resistance extending across the both ends of the active part 101, as in the case of the first embodiment, so as to facilitate the inclusion of the gate resistance inside the semiconductor device.

### Other Embodiments

As described above, the invention has been described according to the first to tenth embodiments, but it should not be understood that the description and drawings implementing a portion of this disclosure limit the invention. Various alternative embodiments of the present invention, examples, and operational techniques will be apparent to those skilled in the art from this disclosure.

While the semiconductor devices according to the first to tenth embodiments have been illustrated with the MOSFET, the present invention can also be applied to an insulated gate bipolar transistor (IGBT) having a configuration using a p⁺-type collector region for the n⁺-type drain region 1.

While the semiconductor devices according to the first to tenth embodiments have been illustrated with the case including SiC, the present invention can also be applied to a semiconductor device including a semiconductor (a wide band-gap semiconductor) having a greater band gap than Si, such as gallium nitride (GaN), diamond (C), or aluminum nitride (AlN).

The semiconductor device according to the present invention is obtained such that the electric field relaxation regions are formed entirely along the side walls and the bottom of the respective trenches by the ion implantation after the formation of the trenches. The semiconductor device needs to be provided with the trenches in the entire area except for the edge, since the bottoms of the trenches are used in order to lead the electric field relaxation regions to be formed at a deep position. It is typically hard to form the gate resistance on the top surface of the substrate with the insulating film interposed, since the trenches are provided in all of the regions other than the edge.

The present invention can decrease the number of the manufacturing steps by use of polysilicon included in the trenches as the inner gate resistance, so as to facilitate the inclusion of the gate resistance inside the semiconductor device accordingly.

Further, the configurations disclosed in the first to tenth embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
a drift layer of a first conductivity-type provided in an active part and a terminal part located along a circumference of the active part;
a base region of a second conductivity-type provided on a top surface side of the drift layer in the active part;
a main region of the first conductivity-type provided on the top surface side of the drift layer in the active part so as to be in contact with the base region;
a gate electrode provided on the top surface side of the drift layer in the active part and buried in a gate trench extending in one direction across both ends of the active part with a gate insulating film interposed;
a gate runner provided on an outer circumferential side of the active part so as to be electrically connected to the gate electrode;
a gate pad provided on an inner side of the gate runner in the active part; and
a resistance layer provided on the top surface side of the drift layer in the active part and buried in a trench for resistance extending in the one direction across the both ends of the active part with an insulating film interposed so as to be electrically connected between the gate pad and the gate runner.

2. The semiconductor device of claim 1, wherein the trench for resistance has a greater depth than the gate trench.

3. The semiconductor device of claim 1, further comprising:
a conductive layer provided on the top surface side of the drift layer and buried in a source trench provided next to the gate trench and extending in one direction across the both ends of the active part with an insulating film interposed; and
an electric field relaxation region of the second conductivity-type provided in contact with a bottom surface and a side surface of the source trench.

4. The semiconductor device of claim 3, wherein the trench for resistance has a depth equal to a depth of the source trench.

5. The semiconductor device of claim 1, wherein:
the semiconductor device comprises a plurality of the trenches for resistance provided separately from each other, and a plurality of the resistance layers buried in the respective trenches for resistance; and
the plural resistance layers are connected in parallel.

6. The semiconductor device of claim 3, wherein:
the semiconductor device comprises a plurality of the trenches for resistance provided separately from each other; and
an interval between the respective trenches for resistance is equal to an interval between the gate trench and the source trench.

7. The semiconductor device of claim 1, further comprising an electric field relaxation region of the second conductivity-type provided in contact with a bottom surface and a side surface of the trench for resistance.

8. The semiconductor device of claim 1, further comprising a conductive layer provided on the top surface side of the drift layer immediately under the gate runner and buried in an outer circumferential-side trench extending in one direction across the both ends of the active part with an insulating film interposed.

9. The semiconductor device of claim 8, wherein the outer circumferential-side trench has a depth equal to a depth of the trench for resistance.

10. The semiconductor device of claim 8, further comprising an electric field relaxation region of the second conductivity-type provided in contact with a bottom surface and a side surface of the outer circumferential-side trench.

11. The semiconductor device of claim 1, wherein the terminal part is provided with a step having a depth equal to a depth of the trench for resistance.

12. The semiconductor device of claim 1, wherein the terminal part is provided with a guard ring of the second conductivity-type.

13. The semiconductor device of claim 1, wherein a position of an upper end of the resistance layer conforms to a position of an upper end of the gate electrode.

14. The semiconductor device of claim 1, wherein an upper end of the resistance layer is located at a higher position than an upper end of the gate electrode.

15. The semiconductor device of claim 14, wherein:
the semiconductor device comprises a plurality of the trenches for resistance provided separately from each other, and a plurality of the resistance layers buried in the respective trenches for resistance; and
the plural resistance layers are connected to each other via a connection part.

16. The semiconductor device of claim 1, wherein:
the semiconductor device comprises a plurality of the trenches for resistance provided separately from each other; and
the plural trenches for resistance include
a first trench having a greater depth than the gate trench, and
a second trench having a depth equal to a depth of the gate trench.

17. The semiconductor device of claim 1, wherein:
the semiconductor device comprises a plurality of the trenches for resistance provided separately from each other, and a plurality of the resistance layers buried in the respective trenches for resistance; and
the plural resistance layers are connected in series.

18. The semiconductor device of claim 1, wherein the drift layer is an epitaxially-grown layer including silicon carbide.

19. The semiconductor device of claim 1, wherein the gate electrode and the resistance layer each include polysilicon.

20. A method of manufacturing a semiconductor device, comprising:
forming a drift layer of a first conductivity-type in an active part and a terminal part located along a circumference of the active part;
forming a base region of a second conductivity-type on a top surface side of the drift layer in the active part;
forming a main region of the first conductivity-type on the top surface side of the drift layer in the active part so as to be in contact with the base region;
forming a gate trench extending in one direction across both ends of the active part on the top surface side of the drift layer in the active part;
burying a gate electrode in the gate trench with a gate insulating film interposed;
forming a gate runner on an outer circumferential side of the active part so as to be electrically connected to the gate electrode;
forming a gate pad on an inner side of the gate runner in the active part;
forming a trench for resistance extending in the one direction across the both ends of the active part on the top surface side of the drift layer in the active part; and
burying a resistance layer in the trench for resistance with an insulating film interposed so as to be electrically connected between the gate pad and the gate runner.
